(19) United States
(12) Patent Application Publication
(10) Pub. No.: US 2006/0261412 A1
(43) Pub. Date: Nov. 23, 2006

(54) Process and electrostatic discharge protection device for the protection of a semiconductor circuit

(76) Inventors: Kai Esmark, Neuried (DE); Martin Streibl, Petershausen (DE)

Correspondence Address: BRINKS HOFER GILSON & LIONE, P.O. BOX 10395, CHICAGO, IL, 60610, US

(21) Appl. No.: 11/387,452

(22) Filed: Mar. 23, 2006

(30) Foreign Application Priority Data
Mar. 23, 2005 (DE) DE102005013478.5

(51) Int. Cl. H01L 23/62

(52) U.S. Cl. 257/355

(57) ABSTRACT

An ESD protection device diverts an overvoltage present on a semiconductor circuit by a heat conducting arrangement arranged in the ESD protection device. The heat conducting arrangement includes contact holes filled with metal and arranged in the vicinity of a hotspot of the ESD protection device to divert heat from the hotspot. The hotspot is thus a critical point with regard to temperature on a discharge path via which the overvoltage is diverted in the case of an ESD.

### PRIORITY CLAIM

This application claims the benefit of priority from German Application No. DE 10 2005 013 478.5, filed Mar. 23, 2005 which is incorporated herein by reference.

### BACKGROUND

1. Technical Field

The invention generally relates to electrostatic discharge (ESD) protection, and particularly a process and a protection device with which a semiconductor circuit can be better protected against ESD.

2. Related Art

Integrated circuits may be protected against electrostatic discharge. This ESD protection may be achieved by appropriate rules regarding the handling of semiconductor circuits. On the other hand, the semiconductor circuit is frequently given a certain intrinsic strength in regard to ESD by a product- and technology-specific ESD protection concept. This ESD protection concept may be largely produced by an “on-chip” integration.

In the following, an ESD protection device or an ESD protection network is understood to mean an arrangement of components conducting ESD current in an ESD event. Thus in an ESD event, components conducting ESD current are either additionally positioned ESD protection elements and/or active elements with a layout suitable for an ESD. FIG. 1 shows an ESD protection network 12 known according to the prior art which is a combination of additionally positioned ESD protection elements 13 and active elements 14 with a layout suitable for an ESD. In the semiconductor circuit 12 shown in FIG. 1, the active elements 14 form, with a layout suitable for an ESD, driver stages of I/O pads. If an overvoltage occurs at a supply voltage terminal VDD, VSS or at input I or output O of the semiconductor circuit 12, i.e. there is an ESD load, then the ESD protection network 12 facilitates a low-ohm discharge path 17 and thus protects the semiconductor circuit 12 from potential overvoltages.

FIG. 2 shows an ESD protection device 1′ in cross-section according to the prior art which comprises a field effect transistor (more specifically a salicide blocked NFET) with drain 2, gate 3 and source 4. The drain 2 is thereby contacted with a series of drain contact holes 5, the gate 3 with a series of gate contact holes 15 (not shown in FIG. 2) and the source 4 with a series of source contact holes 6. An additional series of contact holes 11 contacts a p-substrate contact 10 of the field effect transistor. FIG. 2 shows only one contact hole because it is a cross-section view. The ESD protection device 1′ may be designed with an increased distance between the series of drain contact holes 5 and the gate 3 and with a salicide blocked diffusion.

FIG. 3 shows the ESD protection device 1 shown in FIG. 2 also in cross-section, cut on the plane A shown in FIG. 2. The series of drain contact holes 5 is arranged parallel to the series of source contact holes 6 and the additional series of contact holes 11. Between the gate 3, which is contacted by gate contact holes 15, and the drain contact holes 5, a resistor network 16 is shown schematically. This resistor network 16 must overcome an electrical current on its route from the gate 3 to the drain contact holes 5 in an ESD event. The field effect transistor of the ESD protection device 1′ is designed, because of the increased distance between the gate 3 and the drain contact holes 5, such that the electrical current in an ESD event is extended as far as possible two-dimensionally (sheetlike) so that there is no current filamenting which is shown schematically by the resistor network 16.

If there is an ESD event, a parasitic bipolar transistor of the field effect transistor switches on so that a so-called hotspot 7 (see FIG. 2) occurs at the drain/substrate junction at gate 3 as a result of the Joule effect. FIG. 2 shows the hotspot 7 by a small dark dot on the left under the rectangular gate 3. In addition, FIG. 2 shows a temperature distribution of the ESD protection device 1′ under an ESD load, 100 ns after an overvoltage occurs, with a 6 mA/μm current flowing. The same temperature ranges are shown there with the same grey scale.

The temperature at hotspot 7 rises as the discharge current increases (up to 652K) and can ultimately achieve values at which melting or phase transitions (intrinsic) can occur in the semiconductor material of the field effect transistor, as a result of which the ESD protection device 1′ experiences irreparable damage. This may lead to the failure of the ESD protection device 1′ and, consequently, often of the entire circuit. A maximum current which can flow via the field effect transistor without producing self-destruction of the ESD protection device 1′ is thereby characterised by a parameter Iₜ₂ [mA/μm] and is an intrinsic property of the field effect transistor. The field effect transistor can be an NFET or a PFET. An ESD specification of an I/O library for a semiconductor circuit normally determines the minimum width necessary (and thus an area requirement) of an ESD protection device or an active element with a layout suitable for an ESD so that a specified discharge current can safely flow through it.

The I/O library is, for example, specified at an ESD strength of 2 kV HBM (human body model) which corresponds to a peak current of I_{ESD}=1.3 A. Assuming an intrinsic strength of Iₜ₂=10 mA/μm, a minimum necessary width W for the element in the ESD discharge path of W=I_{ESD}/Iₜ₂=130 μm is produced. If the required increased distance between the drain contact hole 5 and the gate 3 of a few millimetres is added to this, a substantial area is taken up by ESD safety measures alone in the I/O library.

### SUMMARY

An ESD protection system may provide a process and a correspondingly designed ESD protection device with either a smaller area or better ESD strength.

A process for the improved ESD protection of a semiconductor circuit is provided which comprises an ESD protection device. The ESD protection device diverts an overvoltage occurring on the semiconductor circuit. A heat conducting arrangement which consists of materials with a high thermal conductivity compared to an average thermal conductivity of the materials of the semiconductor circuit, is thus arranged in the ESD protection device.

At least one contact hole can be connected to a metal layer which is arranged above the hotspot.

In an ESD event, the metal layer acts as a heat drain due to which heat is diverted from the hotspot to the metal layer via the at least one contact hole.

If the heat conducting arrangement has several contact holes for removing heat which are arranged in the vicinity of the hotspot, there may be two variations with regard to the metal layer.

In a first variation, a certain number of the contact holes have each a metal layer which is connected to the relevant contact hole. Thus the certain number of contact holes can consist of one contact hole, several of these contact holes or all contact holes of the heat conducting arrangement.

In a second variation, the heat conducting arrangement has just one metal layer which is connected to all contact holes of the heat conducting arrangement.

A metal layer may be connected to a number of the contact holes or several metal layers to one or several contact holes.

The ESD protection device and process is suitable for use in ESD protection devices for semiconductor circuits. The ESD protection device however is of course not restricted to th semiconductor circuits but can also be used, for example, to divert heat from other areas of the semiconductor circuit which are not arranged for ESD protection.

### BRIEF DESCRIPTION OF THE DRAWINGS

The present invention is illustrated in greater detail in the following with reference to the attached drawing using preferred embodiments.

FIG. 1 shows an ESD protection network according to the prior art.

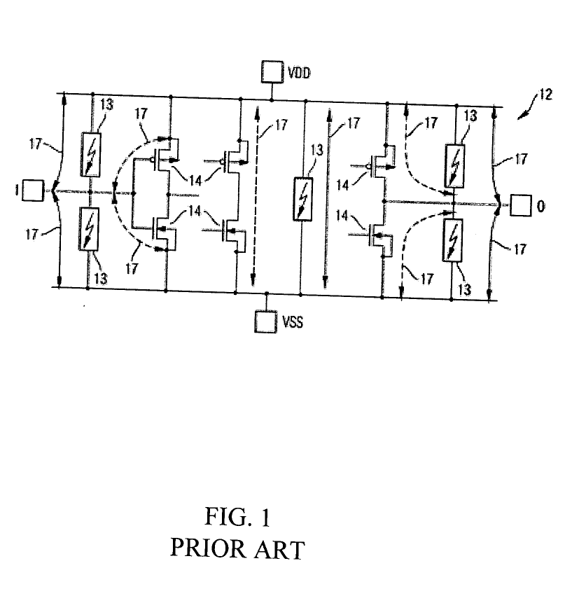

FIG. 2 shows in cross-section an ESD protection device according to the prior art showing in addition a temperature distribution in an ESD event which has a hotspot.

FIG. 3 shows in cross-section (cut according to plane A in FIG. 2) the ESD protection device according to the prior art already shown in FIG. 2.

FIG. 4 shows in cross-section (same angle of view as in FIG. 2) an ESD protection device.

FIG. 5 shows in cross-section (same angle of view as in FIG. 2 and FIG. 4) a the ESD protection device.

FIG. 6 shows a semiconductor circuit with ESD protection.

FIG. 7 illustrates a process for ESD protection of a semiconductor circuit.

### DETAILED DESCRIPTION

While heat is removed by means of the heat conducting arrangement, overheating of the ESD protection device occurs compared with an ESD protection device according to the prior art without the heat conducting arrangement only at higher values for the current density. As a result, the ESD protection device with the heat conducting arrangement has a higher ESD strength compared to an ESD protection device according to the prior art without the heat conducting arrangement with dimensions otherwise the same. Furthermore, it is possible for the ESD protection device with the heat conducting arrangement to be smaller in dimension compared to an ESD protection device according to the prior art without the heat conducting arrangement and therefore have the same ESD strength as the ESD protection device according to the prior art without the heat conducting arrangement. An improvement of the intrinsic ESD strength of the ESD protection device is produced by the layout of the ESD protection device.

A hotspot can thus be located on a discharge path via which the overvoltage is diverted. The hotspot is thus a point on the discharge path which has a temperature during a discharge of the overvoltage which is in an area which is critical with regard to the ESD protection device, i.e. if the temperature rises further at this point there is a failure of the ESD protection device. More specifically, by simulating an ESD event a number of points are determined inside the ESD protection device which have a higher temperature than other points of the ESD protection device. Within this number, a point or the hotspot at which the temperature determined in an ESD event has the lowest distance to a maximum permissible temperature at this point is determined. Thus the heat conducting arrangement which comprises in particular at least one contact hole for removing the heat, is arranged in closer proximity to this hotspot in order to divert heat from the hotspot.

Due to the arrangement of the heat conducting arrangement in the vicinity of the hotspot, the heat is advantageously removed just where a further rise in temperature leads to a failure of the ESD protection device. In other words, any heat accumulating in an ESD event is removed from a particularly critical point in terms of temperature.

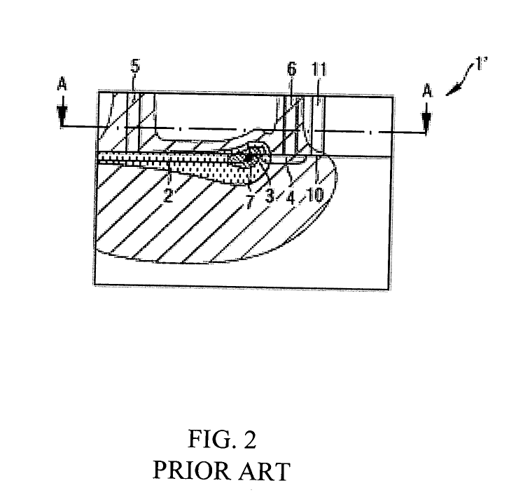

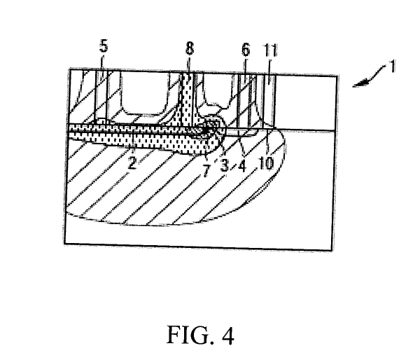

FIG. 4 shows a an ESD protection device 1 in cross-section which includes a field effect transistor (more specifically an NFET) which is similar to the field effect transistor shown in FIG. 2, therefore the same reference numbers denote the same components. In addition to the ESD protection device 1′ shown in FIG. 2, the ESD protection device 1 shown in FIG. 4 includes a series of contact holes 8 which are arranged in the vicinity of the hotspot 7. Of these contact holes 8 which are filled with a metal, such as tungsten, only one contact hole 8 is visible in cross-section due to the cross-sectional representation of FIG. 4.

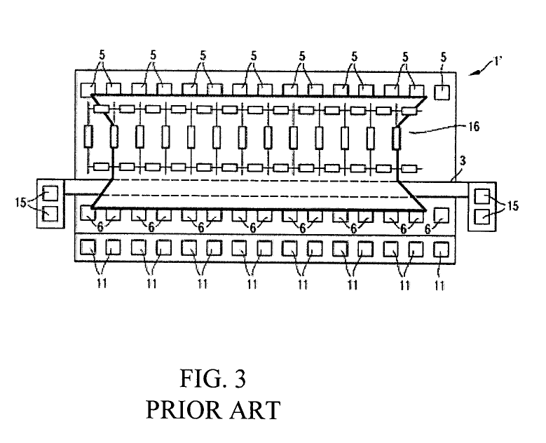

In a representation similar to FIG. 3 of the embodiment according to the invention of the ESD protection device 1, the contact holes 8 for removing heat would be arranged in a series, parallel to the series of drain contact holes 5 or source contact holes 6 between the gate 3 and the drain contact holes 5 in the vicinity of gate 3.

The contact holes 8 of the ESD protection device 1 then act as a thermal drain. The temperature in an area around the contact holes 8, and thus in an area of the hotspot 7 (which according to definition is a critical area of the ESD protection device 1 in terms of temperature), is reduced compared to an ESD protection device 1′. Simulations have shown that with the same injection conditions in the case of ESD of 6 mA/μm (electrical current per width), the maximum temperature in the hotspot 7 can be reduced by the contact holes 8 from 652 K to 620 K.

By further simulations and calculations, it can be shown that due to the presence of the maximum temperature at the hotspot 7 from 652 K to 620 K, an ESD protection device 1 according to the invention can be developed with contact holes 8 with approximately 10% less surface area than an ESD protection device 1′ and nevertheless may have the same ESD strength. An area consumption of the ESD protection device 1 with the same ESD strength is reduced by 10% compared to the ESD protection device 1′.

A significant amount of the available area of a semiconductor circuit is required for ESD protection measures, so a 10 percent savings in area relates to a not insignificant part of the semiconductor circuit.

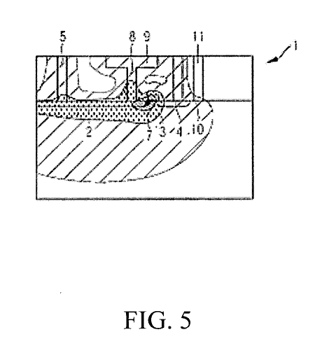

FIG. 5 shows an example ESD protection device 1 which differs from the embodiment shown in FIG. 4 in that each contact hole 8 above the hotspot 7 has an additional metal plane 9 as another thermal drain. Thus, the maximum temperature in the hotspot 7 with otherwise the same injection conditions of 6 mA/μm can be further reduced to 605 K. The area consumption of the ESD protection device 1 according to the invention shown in FIG. 5 at the same ESD strength is reduced by 16% compared to the ESD protection device 1′.

Neither the contact holes 8 in FIG. 4 nor the contact holes with the additional metal layer 9 in FIG. 5 have an electrical function. They are, for example, not connected to other components by wiring.

In FIGS. 4 and 5, as in FIG. 2, a temperature trend is shown for an ESD event, the temperature trends in the three FIGS. 2, 4 and 5 corresponding qualitatively.

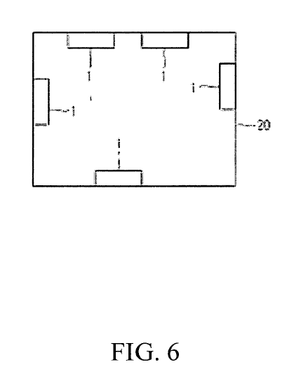

FIG. 6 shows a semiconductor circuit 20 which has several ESD protection devices 1.

Newer semiconductor technologies, such as for example SOI (silicon-on-insulator) present even more critical thermal boundary conditions than the so-called bulk technologies, so that an area savings based on the use of an ESD protection device 1 could be greater with these new semiconductor technologies compared to the usual ESD protection device according to the prior art even more than was previously estimated.

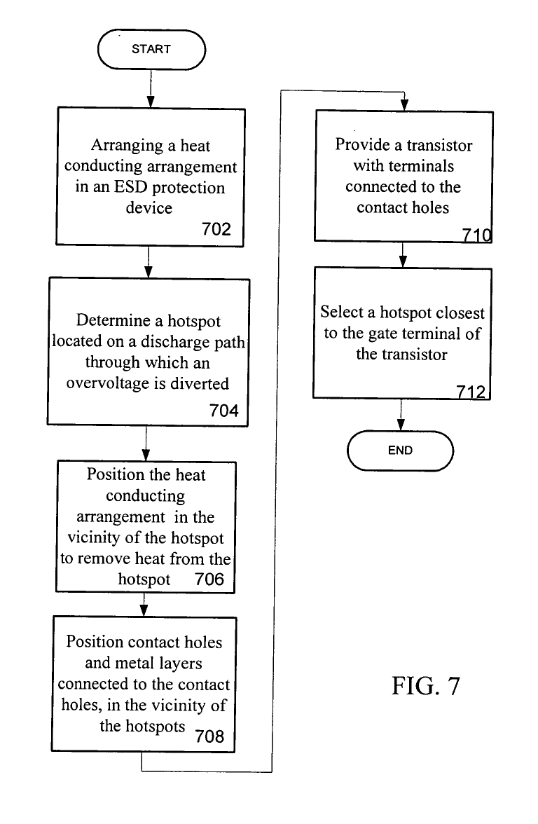

FIG. 7 illustrates a process that protects a semiconductor circuit from ESD. The process diverts an overvoltage present on the semiconductor circuit. The process includes arranging a heat conducting arrangement in the ESD protection device (Act 702) where the heat conducting arrangement has a high thermal conductivity compared to an average thermal conductivity of materials of the semiconductor circuit, in order to remove heat. The process determines a hotspot located on a discharge path through which an overvoltage is diverted (Act 704), where the hotspot has a temperature in a critical range with regard to a failure of the ESD protection device during a discharge of the overvoltage.

The process positions the heat conducting arrangement in the vicinity of the hotspot to remove heat from the hotspot (Act 706). The process positions contact holes and metal layers connected to the contact holes, in the vicinity of the hotspots (Act 708). The contact holes may be positioned above the hotspot.

The process provides a transistor with terminals connected to the contact holes (Act 710). The transistor may be connected such that a distance between the gate terminal of the transistor and at least one terminal contact hole is greater than a distance for a transistor not belonging to the ESD protection device. The transistor may be a field effect transistor, where the gate terminal of the transistor includes a gate of the field effect transistor, and where at least one terminal contact hole is at least a drain contact hole connected to a drain of the field effect transistor.

The process may select the positioning of the transistor with respect to a location of a hotspot with respect to the gate terminal of the transistor (Act 712).

While various embodiments of the invention have been described, it will be apparent to those of ordinary skill in the art that many more embodiments and implementations are possible within the scope of the invention. Accordingly, the invention is not to be restricted except in light of the attached claims and their equivalents.

1. A process for ESD protection of a semiconductor circuit comprising an electrostatic discharge protection (ESD) protection device that diverts an overvoltage present on the semiconductor circuit, comprising:
arranging a heat conducting arrangement in the ESD protection device where the heat conducting arrangement comprises a high thermal conductivity compared to an average thermal conductivity of materials of the semiconductor circuit to remove heat.

2. A process according to claim 1,
further comprising determining a hotspot on a discharge path through which the overvoltage is diverted, where the hotspot comprises a temperature in a critical range with regard to a failure of the ESD protection device during a discharge of the overvoltage.

3. A process according to claim 2,
further comprising positioning
at least one contact hole that removes heat, where the contact hole is positioned in the vicinity of the hotspot.

4. A process according to claim 3,
further comprising positioning a metal layer above the hotspot and connecting the metal layer to at least one contact hole.

5. A process according to claim 2,
further comprising positioning
a plurality of contact holes that remove heat,
in the vicinity of the hotspot, and connecting a metal layer to at least one of the contact holes above the hotshot.

6. (canceled)

7. A process according to claim 5,
where
the ESD protection device comprises a transistor and at least one terminal contact hole connected to a first terminal of the transistor, where a distance between the gate terminal of the transistor and the at least one terminal contact hole is greater than a distance for a transistor not belonging to the ESD protection device.

8. A process according to claim 7,
where
the transistor comprises a field effect transistor, and where
the gate terminal comprises a gate of the field effect transistor, and where
the at least one terminal contact hole is at least a drain contact hole connected to a drain of the field effect transistor.

9. Process according to claim 7,
comprising selecting
a hotspot for the heat conducting arrangement closest to the gate terminal of the transistor of the ESD protection device if there are more than one hotspots on the discharge path.

10. A process according to claim 5,
comprising selecting
a distance between the contact holes to be minimal such that the distance is compatible with design rules for the semiconductor circuit.

11. A process according to claim 5,
comprising filling
the contact holes with metal.

12. A process according to claim 1,
comprising electrically isolating
the heat conducting arrangement from other components of the semiconductor circuit.

13. A process according to claim 2,
comprising arranging
the heat conducting arrangement such that an electrical resistance of the discharge path is not reduced compared to an ESD protection device in which no heat conducting arrangement is present.

14. An ESD protection device for a semiconductor circuit developed such that it diverts an overvoltage present on the semiconductor circuit, comprising:
a heat conducting arrangement which has a high thermal conductivity compared to an average thermal conductivity of materials of the semiconductor circuit to remove heat.

15. An ESD protection device according to claim 14,
where
the heat conducting arrangement is arranged in the vicinity of a hotspot such that heat is removed from the hotspot, and where the hotspot is a point on a discharge path via which the overvoltage is diverted.

16. An ESD protection device according to claim 15,
where
the heat conducting arrangement comprises at least one contact hole that removes the heat which is arranged in the vicinity of the hotspot.

17. An ESD protection device according to claim 16,
where
a metal layer of the heat conducting arrangement is arranged above the hotspot, where the metal layer is connected to the at least one contact hole.

18. An ESD protection device according to claim 14,
where
the heat conducting arrangement comprises contact holes that remove the heat, and where
the contact holes are arranged in the vicinity of the hotspot.

19. An ESD protection device according to claim 18,
where
the heat conducting arrangement comprises a metal layer which is connected to the contact holes and is arranged above the hotspot.

20. An ESD protection device according to claim 18,
where
the ESD protection device comprises a transistor and at least one terminal contact hole connected to a first terminal of the transistor, where a distance between the gate terminal of the transistor and the at least one terminal contact hole is greater than with a transistor not belonging to the ESD protection device.

21. An ESD protection device according to claim 20,
where
the transistor comprises a field effect transistor, where
the gate terminal comprises a gate of the field effect transistor, and where
the at least one terminal contact hole comprises at least a drain contact hole which is connected to a drain of the field effect transistor.

22. An ESD protection device according to claim 20,
where
the hotspot which is closest to the gate terminal of the transistor of the ESD protection device is selected for the heat conducting arrangement if there are more than one hotspots on the discharge path.

23. An ESD protection device according to claim 18,
where
a distance between the contact holes is selected to be minimal such that it is compatible with design rules in for the semiconductor circuit.

24. An ESD protection device according to claim 18,
where
the contact holes are filled with metal.

25. An ESD protection device according to claim 14,
where
the heat conducting arrangement is electrically isolated from other components of the semiconductor circuit.

26. An ESD protection device according to claim 15,
where an electrical resistance of the discharge path is not reduced compared to an ESD protection device that does not comprise a heat conducting arrangement.

27. (canceled)

28. (canceled)

29. An ESD protection device for a semiconductor circuit that diverts an overvoltage present on the semiconductor circuit, comprising:
means for removing heat from a hotspot,
where the hotspot comprises a point on a discharge path through which the overvoltage is diverted, and where the hotspot during a discharge of the overvoltage has a temperature which is in a critical range with regard to a failure of the ESD protection device.

30. A process according to claim 2, further comprising positioning the heat conducting arrangement in the vicinity of the hotspot to remove heat from the hotspot.

31. An ESD protection device according to claim 16, where the hotspot, during a discharge of the overvoltage, has a temperature which is in a critical range with regard to a failure of the ESD protection device.

32. An ESD protection device according to claim 20, further comprising a metal layer arranged above the hotspot for at least one of the contact holes, where the metal layer is connected to relevant contact hole.

33. A device according to claim 7, where the discharge path runs via the at least one terminal contact hole, and where the contact holes run on a straight line between the at least one terminal contact hole and the gate terminal.
